(19) United States
(12) Patent Application Publication
(10) Pub. No.: US 2014/0198431 A1
(43) Pub. Date: Jul. 17, 2014

(54) Apparatus electrically coupled to a low wall outlet that is configured for easy viewing of a display

(71) Applicant: MARK MEDLEY, COVINA, CA (US)

(72) Inventor: MARK MEDLEY, COVINA, CA (US)

(21) Appl. No.: 13/385,616

(22) Filed: Jan. 14, 2013

(51) Int. Cl. H05K 5/00

(52) U.S. Cl. CPC H05K 5/0017
USPC 361/679.01

(57) ABSTRACT

Generally disclosed is an intermediary apparatus for an electric wall outlet and an electric device. The apparatus features a display or control that is easily viewable at low heights.

### CROSS-REFERENCE TO RELATED APPLICATIONS

Not Applicable.

### STATEMENT REGARDING FEDERALLY SPONSORED RESEARCH OR DEVELOPMENT

Not applicable.

### BACKGROUND OF THE INVENTION

1. Field of Invention

This disclosure is in the field of electrical outlet intermediaries with a display.

2. Background of the Invention

Many apparatus exist which are electrically coupled to an electrical outlet as an intermediary between an electric device and the wall outlet. Sometimes the intermediary apparatus features a display for communicating information or a control for operating the apparatus. These displays or controls are not easily interacted with by a user, particularly when the electrical outlet is low or near the ground. Thus a need exists for intermediaries of an electric device and wall outlet with displays or controls that are easily operated.

### SUMMARY OF THE INVENTION

In view of the foregoing, it is an object of this disclosure to describe intermediate apparatus for electrical devices and electrical wall sockets wherein the apparatus features displays or controls that are easily operated. In one embodiment the intermediate apparatus comprises: a housing with a back that defines a first plane; and display or control in said housing that occupies a second plane; wherein the second plane is oblique to the first plane; and, wherein a plug is in the first plane for electrically coupling the housing to an electrical wall socket. In use, the apparatus may be coupled to a wall socket and then coupled to an electric device. In another embodiment, the disclosed apparatus comprises: a housing with a back that defines a first plane; and a projection on the back that defines a second plane; wherein the second plane is oblique to the first plane; and, wherein a plug is in the second plane for electrically coupling the housing to an electrical wall socket. In operation, either the first or second plane will be typically be parallel with the wall so that a display or control panel occupies a plane that is oblique to the wall.

Other objectives and desires may become apparent to one of skill in the art after reading the below disclosure and viewing the associated figures.

### BRIEF DESCRIPTION OF THE FIGURES

The manner in which these objectives and other desirable characteristics can be obtained is explained in the following description and attached figures in which:

FIG. 1A is a perspective view of an intermediary between an electrical outlet and an electric device;

FIG. 2A is a front view of the intermediary of FIG. 1A;

FIG. 3A is a rear view of the intermediary of FIG. 1A;

FIG. 4A is a side view of the intermediary of FIG. 1A;

FIG. 5A is another side view of the intermediary of FIG. 1A;

FIG. 6A is a top view of the intermediary of FIG. 1A;

FIG. 7A is a bottom view of the intermediary of FIG. 1A;

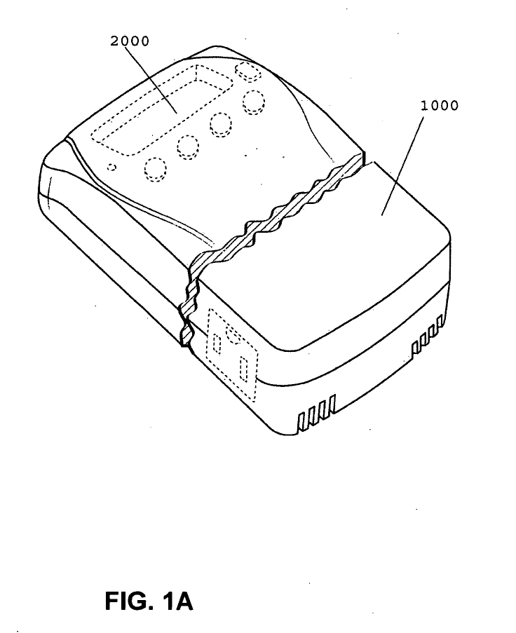

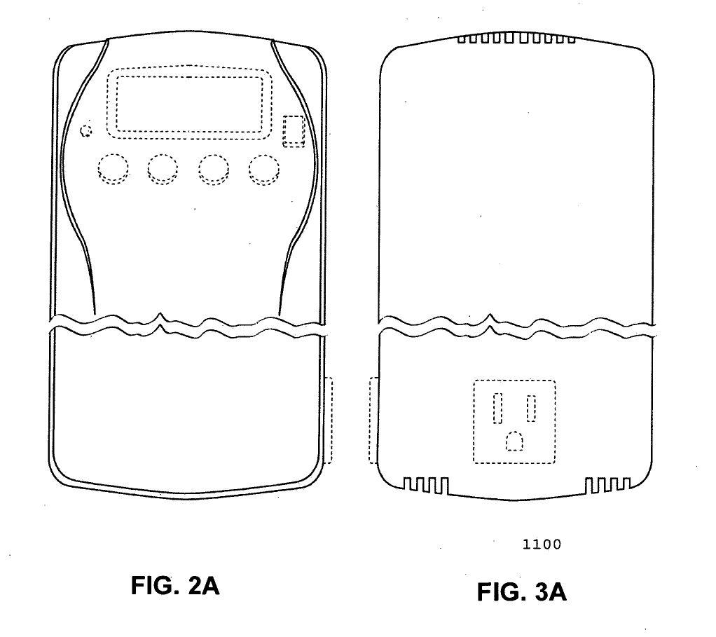

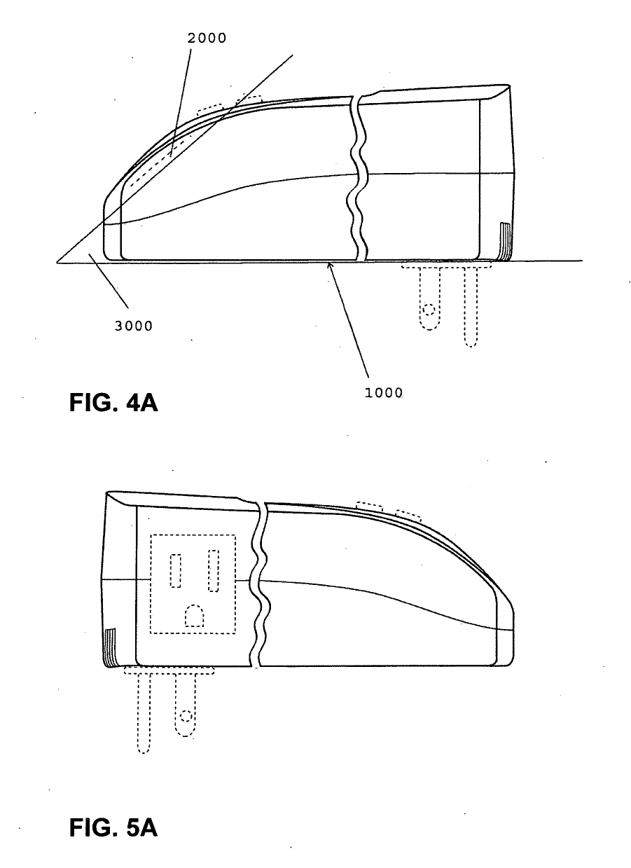

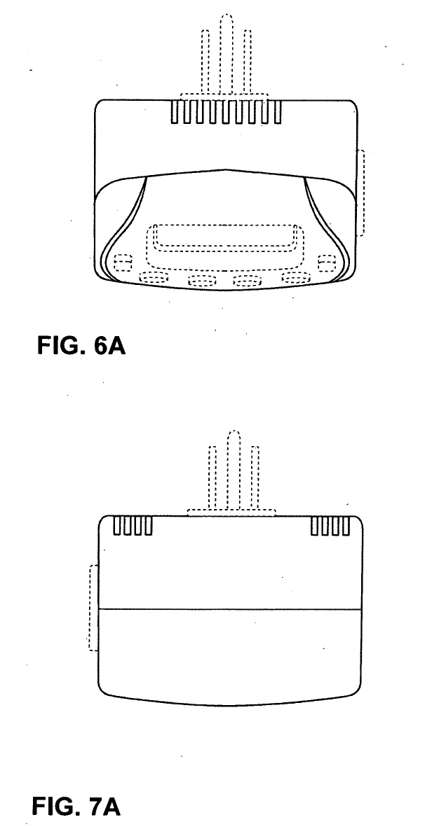

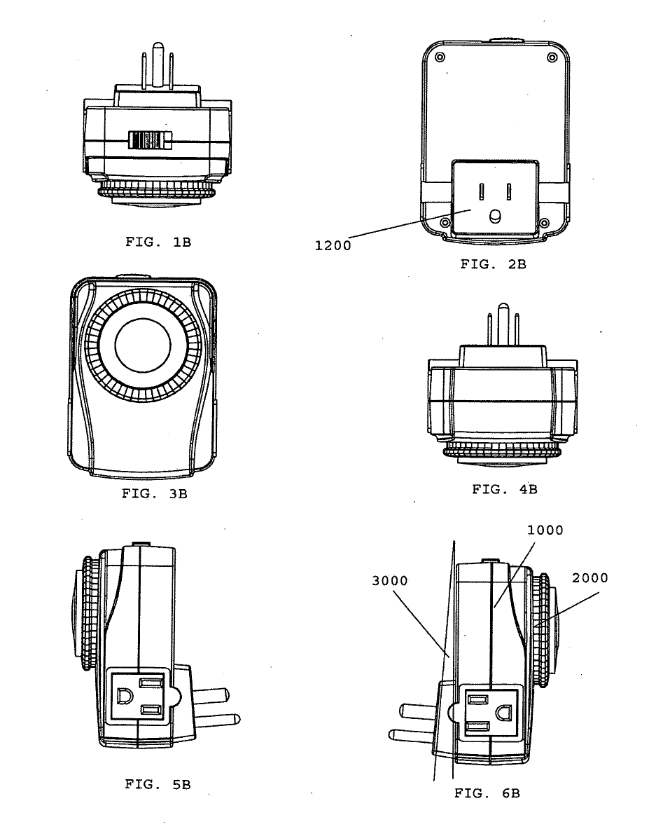

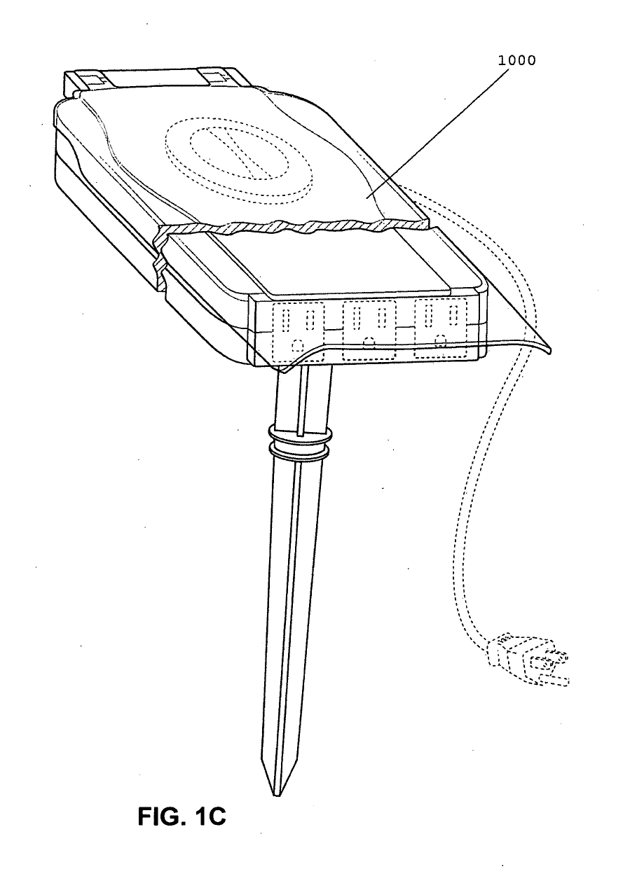

FIG. 1B is a top view of another embodiment of an intermediary between an electrical outlet and an electric device;

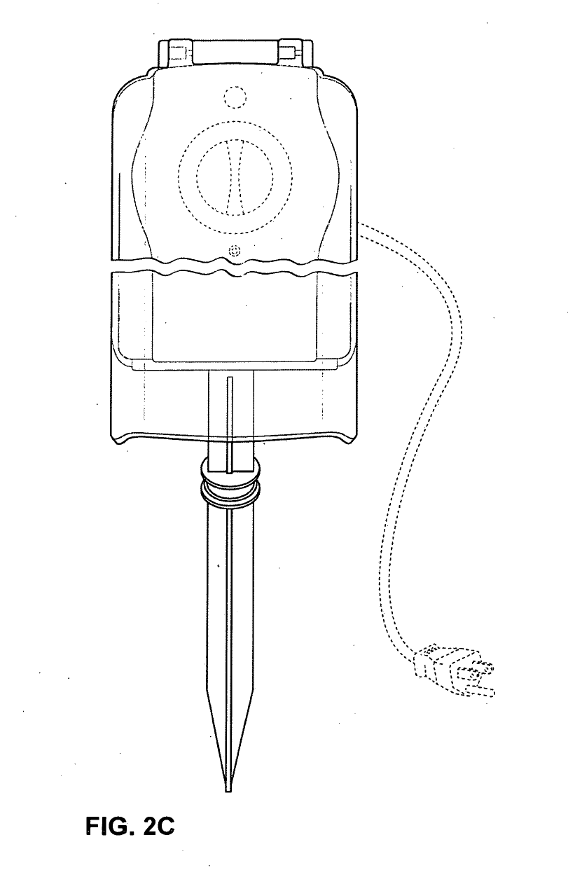

FIG. 2B is a rear view of the intermediary of FIG. 1B;

FIG. 3B is a front view of the intermediary of FIG. 1B;

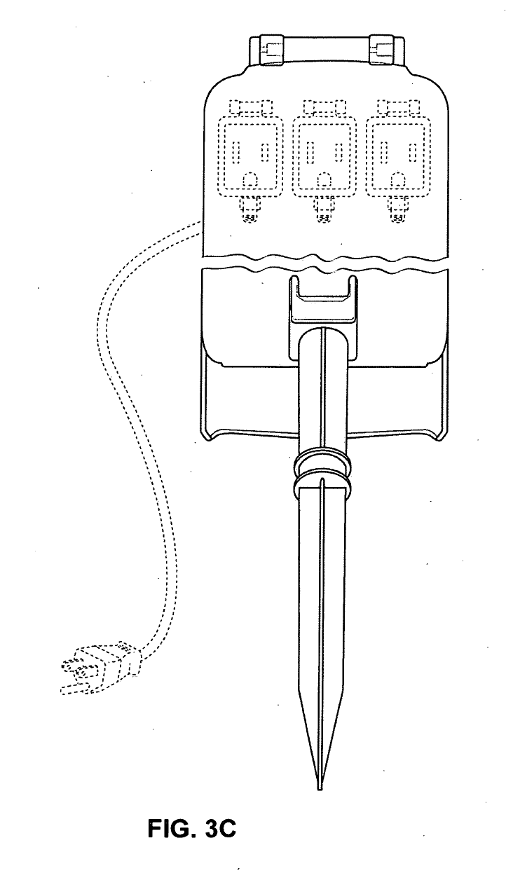

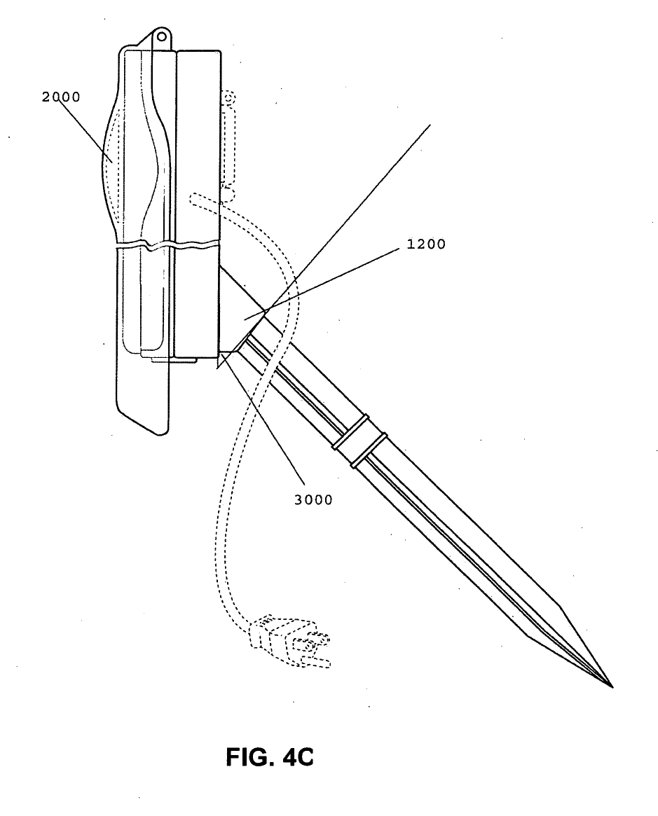

FIG. 4B is a bottom view of the intermediary of FIG. 1B;

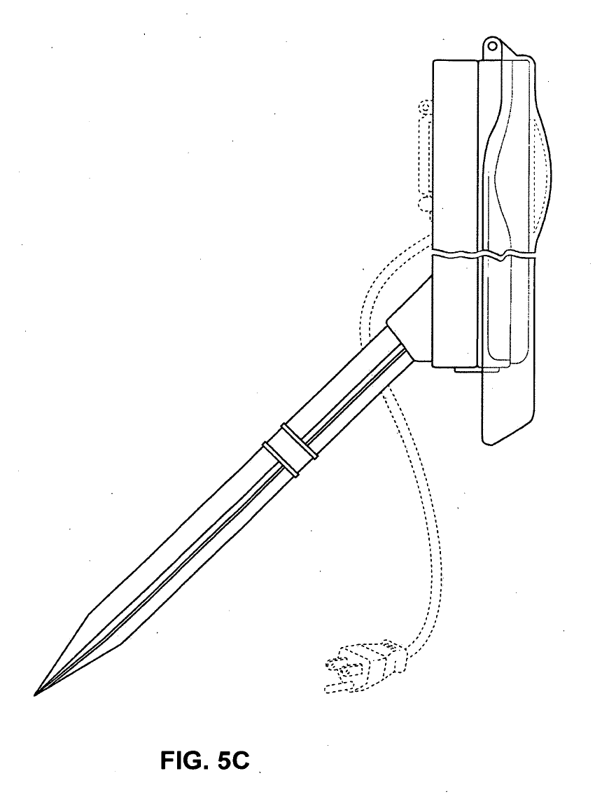

FIG. 5B is a side view of the intermediary of FIG. 1B;

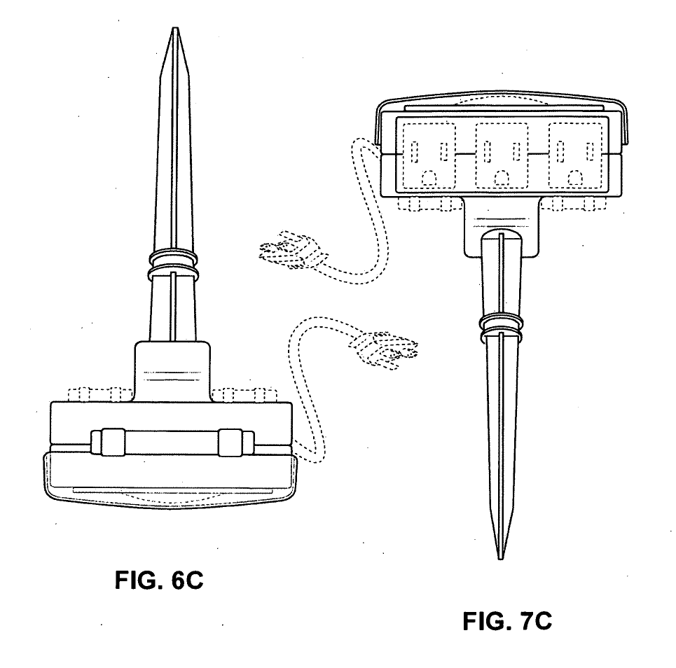

FIG. 6B is another side view of the intermediary of FIG. 1B;

FIG. 1C is a perspective view of another embodiment of an intermediary between an electrical outlet and an electric device;

FIG. 2C is a front view of the intermediary of FIG. 1C;

FIG. 3C is a rear view of the intermediary of FIG. 1C;

FIG. 4C is a side view of the intermediary of FIG. 1C;

FIG. 5C is another side view of the intermediary of FIG. 1C;

FIG. 6C is a top view of the intermediary of FIG. 1C;

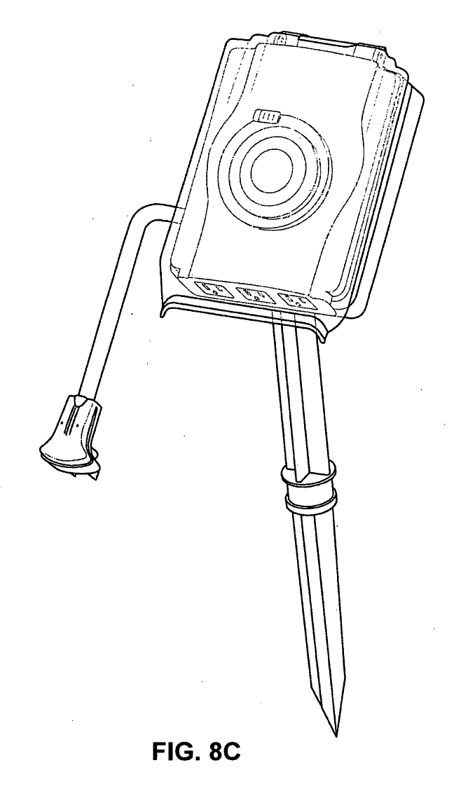

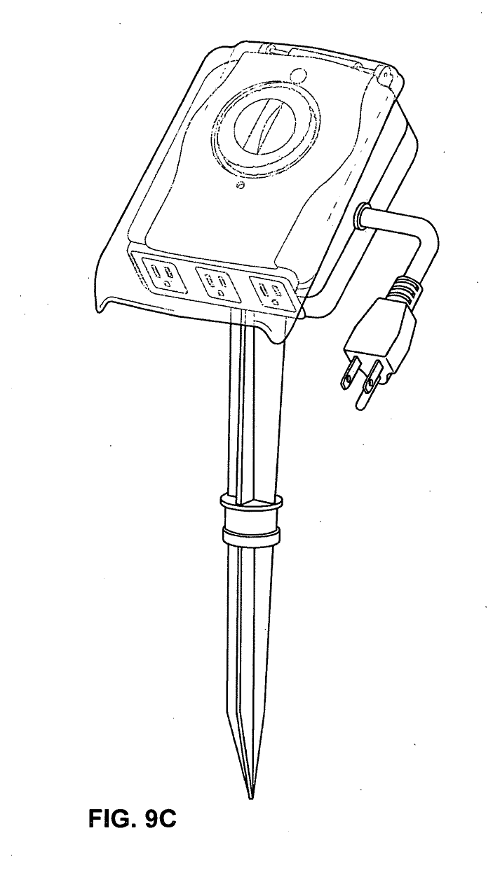

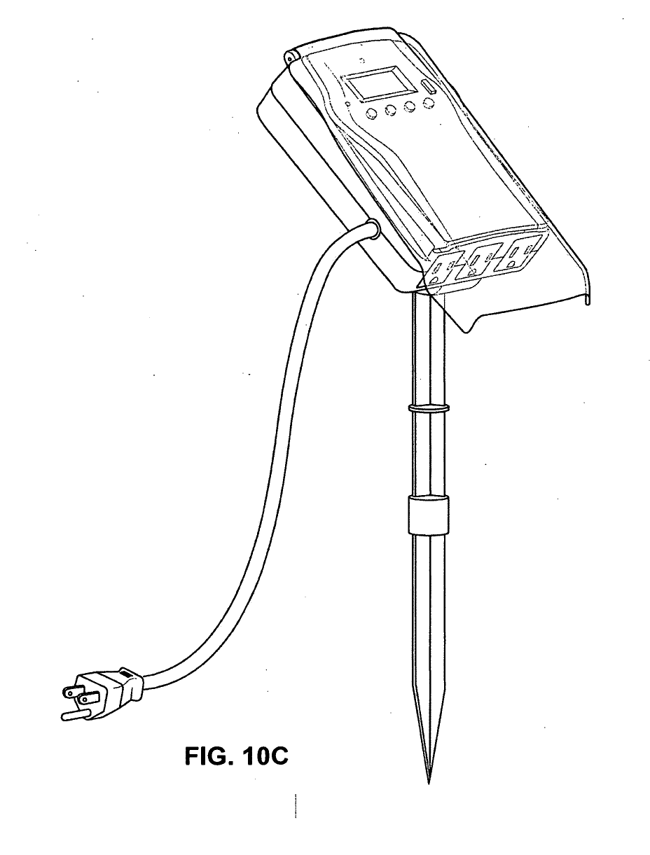

FIG. 7C is a bottom view of the intermediary of FIG. 1C;

FIG. 8C is another perspective view of an intermediary device;

FIG. 9C is another perspective of an intermediary device; and,

FIG. 10C is another perspective of an intermediary device.

Items drawn in dashed or broken lines might also be considered drawn in solid lines.

It is to be noted, however, that the appended figures illustrate only typical embodiments of the disclosed apparatus, and therefore, are not to be considered limiting of their scope, for the disclosed systems may admit to other equally effective embodiments that will be appreciated by those reasonably skilled in the relevant arts. Also, figures are not necessarily made to scale.

### DETAILED DESCRIPTION OF PREFERRED EMBODIMENTS

Generally described is an intermediate apparatus for electrical devices and electrical wall sockets wherein the apparatus features displays or controls that are easily operated. In one embodiment the intermediate apparatus comprises: a housing with a back that defines a first plane; and display or control in said housing that occupies a second plane; wherein the second plane is oblique to the first plane; and, wherein a plug is in the first plane for electrically coupling the housing to an electrical wall socket. In use, the apparatus may be coupled to a wall socket and then coupled to an electric device. In another embodiment, the disclosed apparatus comprises: a housing with a back that defines a first plane; and a projection on the back that defines a second plane; wherein the second plane is oblique to the first plane; and, wherein a plug is in the second plane for electrically coupling the housing to an electrical wall socket. In operation, either the first or second plane will be parallel with the wall so that a display or control panel occupies a plane that is oblique to the wall.

FIG. 1A through 7A respectively depict perspective, front, back, left side, right side, top, and bottom views of the disclosed intermediate apparatus 1000 for an electric device and a wall outlet. As shown, the apparatus features a block housing 1000 with an electric plug 1100 protruding from its back for insertion into an electrical socket, and an angled digital display 2000 on its face. Referring to FIG. 4, the digital display is preferably presented to a user via a window and positioned so that a user may view the display while the intermediate device is coupled to a low wall socket. Suitably, this configuration is the result of the back of the housing 1000 defining a first plane (e.g., a vertical plane) and the digital display defining a plane that is oblique to the first plane. Suitably, the oblique planes define an angle 3000 that is between 0 and 90 degrees, with 11.5 degrees being one preferable embodiment.

FIGS. 1B through 6B respectively depict front, back, left side, right side, top, and bottom views of the disclosed intermediate apparatus 1000 for an electric device and a wall outlet. As shown, the apparatus features a block housing 1000 with a projection 1200 protruding from its back and a dial 2000 on its face. The projection features an electric plug 1100 for is insertion into an electrical socket. Referring to FIG. 6B, the dial 2000 is preferably presented to a user and positioned so that a user may view the display while the intermediate device is coupled to a low wall socket. Suitably, this configuration is the result of the back of the housing 1000 defining a first plane and the projection defining a second plane that is oblique to the first plane. Suitably, the oblique planes define an angle 3000 that is between 0 and 90 degrees, with 11.5 degrees being one preferable embodiment.

FIGS. 1C through 10C respectively depict perspective front, back, left side, right side, top, bottom and three perspective views of the disclosed intermediate apparatus 1000 for an electric device and a wall outlet. As shown, the apparatus features a block housing 1000 with a projection 1200 protruding from its back and a dial 2000 on its face. The projection features a stake receptacle 1100 for retention of a ground stake. Referring to FIG. 4B, the dial 2000 is preferably presented to a user and positioned so that a user may view the display while the intermediate device is coupled to the top of a ground stake, as shown. Suitably, this configuration is the result of the back of the housing 1000 defining a first plane and the projection defining a second plane that is oblique to the first plane. Suitably, the oblique planes define an angle 3000 that is between 15 and 75 degrees, with 45 degrees being preferable.

The disclosed apparatus may be constructed of any suitable materials and methodologies known for the construction of electrical intermediary apparatus. It should be noted that FIGS. 1 through 10 and the associated description are of illustrative importance only. In other words, the depiction and descriptions of the present disclosure should not be construed as limiting of the subject matter in this application. Additional modifications may become apparent to one skilled in the art after reading this disclosure.

In summary, what is disclosed is an intermediary for an electrical device and wall outlet, said intermediary comprising:

a housing with projection on its back and a control or display on its face;
wherein the back defines a first plane;
wherein the projection defines a second plane;
wherein the first and second planes are oblique relative to one another.
Operably, one of the planes may be parallel to a wall so that the other plane is more easily viewed while the apparatus is coupled to a low wall mount.

We claim:

1. An intermediary for an electrical device and wall outlet, said intermediary comprising:
a housing with a projection on a back thereof and a control on a face thereof;
wherein the back defines a first plane;
wherein the projection defines a second plane;
wherein the first and second planes are oblique relative to one another.

2. The apparatus of claim 1 wherein one of the first or second planes are parallel to a wall.
